(19) United States
(12) Patent Application Publication
(10) Pub. No.: US 2004/0257782 A1
(43) Pub. Date: Dec. 23, 2004

(54) Electronic unit as well as method for manufacturing an electronic unit

(76) Inventor: Nikolaus Kerner, Wenzenbach (DE)

Correspondence Address: BAKER BOTTS L.L.P., PATENT DEPARTMENT, 98 SAN JACINTO BLVD., SUITE 1500, AUSTIN, TX, 78701-4039, US

(21) Appl. No.: 10/854,012

(22) Filed: May 26, 2004

(30) Foreign Application Priority Data
May 27, 2003 (DE) 10324047.0

(51) Int. Cl. G01R 1/00; H05K 7/14; H05K 7/18

(52) U.S. Cl. 361/797

(57) ABSTRACT

Electronic unit, especially control unit for a motor vehicle, with a plurality of circuit boards arranged above one another and equipped with electronic components, electrical connection means for electrical interconnection of the circuit boards and a housing arrangement to accommodate the circuit boards, characterized in that, the electrical means of connection consist of a spacer arranged between two adjacent circuit boards and providing an electrical connection of these two circuit boards and that a force is exerted by means of a housing arrangement which presses the circuit boards together and clamps the spacer between the two circuit boards.

### PRIORITY

This application claims foreign priority to German application number 10324047.0 filed May 27, 2003.

### FIELD OF THE INVENTION

The present invention relates to an electronic unit, especially a control unit for a motor vehicle, as well as to a method for manufacturing the electronic unit.

### BACKGROUND OF THE INVENTION

Control units for control of electrical and electronic motor vehicle components (e.g. engine controllers) are well known from the area of motor vehicle electronics, in which, for reasons of space, two circuit boards are arranged one above the other accommodated in a housing and interconnected electrically by electrical connection means.

The electrical connection of the circuit boards in this case is implemented with flexible circuit board connectors (so-called “flex jumpers”) for example. This type of flexible circuit board connector consists as a rule of a plastic foil with layers of copper tracks and, when the control unit is installed, is soldered on both sides to the corresponding conductor tracks of the circuit boards to be interconnected. This represents a relatively expensive connection technology and generates significant costs as a result of the additional operations necessary for electrical connection of the two circuit boards.

To avoid these additional operations, what are known as “rigid-flex circuit boards” have already been developed, in which a flexible circuit board section is provided between two rigid circuit board sections. This circuit board construction has been capable of replacing the two circuit boards soldered to each other and then subsequently connected in a control unit mentioned above in that this circuit board construction is used “folded”, so that the two rigid circuit board sections form the circuit boards arranged above one another and these are already inherently electrically connected to one another (via the flexible section). Even if the additional operations are dispensed with in this solution, this solution is in no way less expensive since producing this type of circuit board construction involves much greater effort than manufacturing rigid circuit boards.

### SUMMARY OF THE INVENTION

The object of the invention is thus to simplify the electrical connection of circuit boards arranged above one another.

This object is achieved with an electronic unit having the following: a plurality of circuit boards arranged one above the other and equipped with at least a first electronic component, a spacer between adjacent boards to form an electrical interconnection between adjacent boards, a housing to accept the circuit boards, said housing pressing the circuit boards together to hold the spacer between the boards, and at least one second electronic component attached to the spacer having at least one connection pin in electrical contact with one of the circuit boards.

The object of the invention is achieved by a method for manufacturing an electronic unit comprising: arranging a plurality of circuit boards equipped with at least one electronic component above one another in a housing, electrically connecting the circuit boards to each other by arranging a spacer between adjacent circuit boards to provide an electrical connection between adjacent circuit boards, pressing the adjacent boards together via a force provided by the housing, and attaching at least one second electronic component to the spacer via at least one connection pin of said second component to make an electrical contact with one of the adjacent boards.

Of significance for the invention is the arrangement of at least one spacer between two adjacent circuit boards which provides the electrical connection of these two circuit boards. The spacer thus has a mechanical function of guaranteeing a desired spacing between the boards and at the same time has an electrical function for providing the electrical connection between the boards. When the electronic unit is manufactured it is a very simple task to arrange such a spacer between two adjacent boards (in the finished electronic unit). This operation during installation of the electronic unit involves negligible outlay and permits the use of rigid and thereby low-cost circuit boards.

In addition the invention has numerous further advantages. For example, the circuit boards concerned can be connected to each other electrically at practically any point. With conventional connection technology with a flexible circuit board connector or a flexible circuit board section on the other hand only one connection between two immediately adjacent circuit board edges makes sense. The invention thus creates a great degree of freedom as regards the spatial arrangement of the conductor tracks or circuit broad connecting surfaces provided for electrical connection with an adjacent circuit board. This in its turn allows greater flexibility in the circuit board layout.

Furthermore the invention easily allows more than two circuit boards to be interconnected, should this be required or necessary for space reasons (e.g. with extensive electronics). It is then a simple matter to add at least one such spacer between each pair of circuit boards to be electrically interconnected.

Finally the invention opens up interesting options as regards equipping the circuit boards with electronic components. Namely some of these electrical components could be integrated into the electronic unit by initially arranging the components on the spacer or spacers and only making the electrical connection between these components and one or the other of the two adjacent circuit boards as part of the assembly of the electronic unit. Making this electrical connection afterwards is for example of particular interest for components for which connection would be difficult during the process of manufacturing the circuit board, where waves soldering would be required for example. These “exotic” components can then be initially left out and during the manufacturing of the circuit boards with a relatively simple soldering process and electrically contacted during the installation of the electronic unit together with the spacer or spacers.

Because of the generally lower costs for rigid circuit boards there is provision in a preferred embodiment for at least a part, or especially all of the circuit boards of the electronic unit to be rigid.

For efficient utilization of the space in the housing arrangement it is advantageous for the two circuit boards (connected by means of a spacer) to have essentially the same format and essentially be arranged one above the other so that they cover the same area.

The spacer needs installation space. For the spacer to fulfill its function it is not necessary for the spacer to extend very far orthogonally to the vertical direction, that is in parallel to the circuit board surfaces. It is thus preferred, especially to save space, for the spacer to feature at least one cut-out which essentially runs in a straight line lengthwise and/or which extends from one of edge to an opposite edge of one of the two circuit boards and/or which extends lengthwise along one edge of the two circuit boards.

It is also advantageous for the spacer to have at least one section which extends outwards beyond the edge of one of the two circuit boards. The extension outside the space occupied by the circuit board increases the space available for equipping this circuit board with electronic components. In addition an extension beyond the edge of the circuit board offers advantages as regards the connection of the housing arrangement to the complex formed from the circuit boards and spacer(s).

In a preferred embodiment there is provision for the spacer to feature at least one section which extends as a frame around the circumference of one of the two circuit boards. This represents a particularly space-saving spacer design which also offers great mechanical stability with simultaneous low use of materials, especially when this spacer section forms a self-contained frame. This should naturally not exclude the possibility of spurs running inwards being connected to this frame-type section, for example to accommodate the components mentioned above for which contact is to be established later.

In a preferred embodiment a spacer with a one-piece molded plastic body is provided between the two circuit boards, to or through which run a plurality of electrically-conducting, e.g. metallic (preferably lengthwise) connection elements, each of which is embodied as an electrical contact for establishing contact to the adjacent circuit boards. An especially simple form of contacting is produced here if the ends of this connecting element are each in a direct electrical contact with a conductor track or conductor surface. In this case the connection elements are preferably embodied as elastic (spring) contacts. Alternatively these types of connection elements can also be contacted using electrically-conducting parts, which for their part are connected to the relevant circuit board. These parts can for example be contact pins soldered on or soldered into holes in the conductor tracks, known as “press-fit pins” or what are known as “insulation displacement contacts” which function as an intermediary between of the connection element of the spacer and a conductor track or conductor surface of the circuit board.

A simple design is produced if the spacers feature a plurality of electrically-conducting connection elements arranged alongside each other of which the ends (particularly curved ends) are each embodied as an electrical contact for contacting the circuit board concerned.

In a further embodiment there is provision for an electronic component to be held on the spacer in such a way, e.g. glued on or attached by a snap-fit connection, that at least one connection pin of this component is in electrical contact with one of the two circuit boards. “Press-fit pins”, “insulation displacement contacts” can again be provided here as intermediate elements. This mounting of electronic components on the spacer is of particular interest for those electronic components for which direct connection with a circuit board within the framework of manufacturing this circuit board would require a comparatively greater effort, e.g. a special soldering process.

With conventional electronic units connector strips are as a rule, connected to a circuit board using a soldering technique so that the electronic unit can be connected to an external cable arrangement, in that internal connection pins of this connector strip are soldered onto the circuit board or are soldered into holes in this circuit board. Even though this type of integration of a connector strip can also be used with the electronic unit in accordance with the invention, the invention allows as an alternative or additionally a very simple connection of a connector strip whereby the spacer features at least one cutout, in which a connector strip for connecting the electronic unit to an external cable arrangement is accommodated such that at least a part of the internal connection pins of this connector strip are in electrical contact with one or the other of the two circuit boards. In the simplest case these connection pins again form spring contacts which rest elastically in direct contact with the circuit board concerned (on a conductor track or surface). As an alternative to this these connection pins can however also be connected electrically to the circuit board via an intermediate section such as an insulation displacement contact or similar connected to the circuit board by soldering.

There is provision in one embodiment for the housing arrangement to feature a lower housing cover as well as an upper housing cover connected to it. The connection can be made here for example by means of screws, rivets etc. or by a snap-fit connection, welding, heat sealing etc.

In accordance with the invention the electrical connection between the circuit boards can advantageously be made at the same time as the housing arrangement is closed, so that the electrical connection between the circuit boards is not implemented by separate operations intended for this particular purpose. For example during the installation of the electronic unit its components or modules can be stacked above each other in the following sequence: lower housing cover, first circuit board group, spacer frame, spacer frame (if necessary with the connector strip(s) and/or further electronic components), second circuit board group (if necessary further spacer frames and further circuit board groups), upper housing cover. By connecting the two housing covers to each other, for example using a means of connection at such as screws, rivets, clips, flanges, the housing arrangement can be closed and at the same time electrical contact established between the circuit boards.

### BRIEF DESCRIPTION OF THE DRAWINGS

The invention is explained in more detail below on the basis of a number of exemplary embodiments with reference to the enclosed drawings. These show:

FIG. 1 a schematic cross-sectional view of a module formed from two circuit boards with a spacer arrangement inserted between them of an electronic unit in accordance with the first exemplary embodiment,

FIGS. 2-4 schematic overhead views of spacer arrangements in accordance with further exemplary embodiments,

FIGS. 5-9 schematic cross sectional views of spacers in the area of electrically-conductive connection elements in accordance with further exemplary embodiments,

FIGS. 10-14 various views of an electronic unit in accordance with a further exemplary embodiment, namely

FIG. 10 a perspective exploded view,

FIG. 11 a perspective view in the assembled state,

FIG. 12 a perspective, partly cross-sectional view,

FIG. 13 a cross-sectional view along the line XIII-XIII In FIG. 11 and

FIG. 14 a cross sectional view along the line XIV-XIV In FIG. 11.

### DETAILED DESCRIPTION OF THE PREFERRED EMBODIMENTS

The reference numbers of components provided a number of times in an embodiment, but similar in their effect, are consecutively numbered (supplemented by a hyphen and a sequence number in each case). Reference is also made below to such individual components or to the totality of such components by the reference number without any additions.

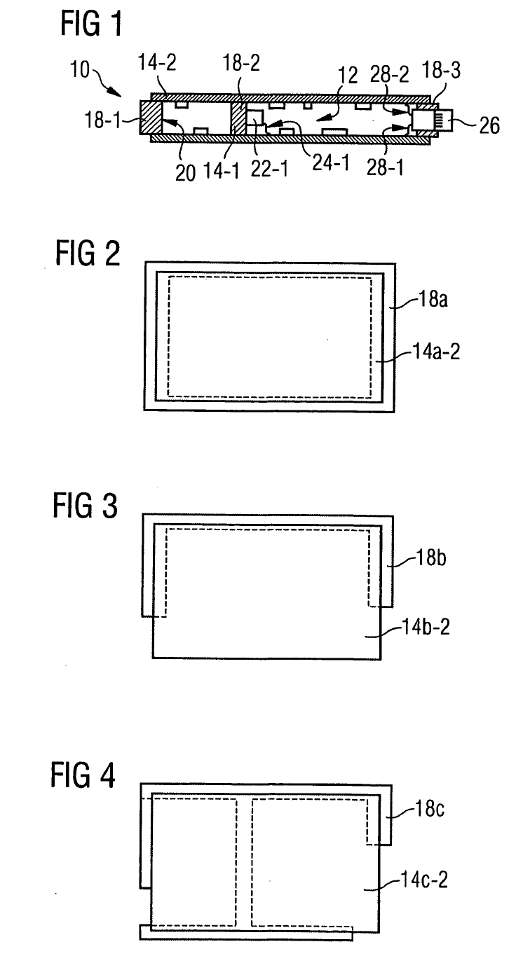

FIG. 1 shows an electronic unit referred to as a whole by the number 10 with two circuit boards arranged to one above the other 14-1 (lower circuit board) and 14-2 (upper circuit board) equipped in the known way with electronic components. A housing enclosing the arrangement shown (not shown in the diagram) exerts a force which presses the circuit boards 14 onto each other. The circuit boards 14 are however held in the position shown or supported by a suitable spacer arrangement of which three sections 18-1, 18-2, and 18-3 are to be seen in the illustration in FIG. 1. This spacer arrangement 18 is a clamped between these circuit boards by the force exerted by the housing on the circuit boards and thus defines the distance between the two circuit boards. In addition an electrical connection between the two circuit boards 14-1, 14-2 adjacent to this arrangement 18 is provided by the spacer arrangement 18, and this is done by electrically-conductive connecting elements extending vertically, of which one, labeled 20, can be seen in FIG. 1.

An electronic component 22-1 of which a connecting pin 24-1, with its end resting sprung against a conductor track of the lower circuit board 14-1 and thus making contact with it, is mounted on spacer section 18-2.

Spacer section 18-3 features a cutout into which a conductor strip 26 for connecting the electronic unit 10 to an external cable arrangement (not shown) is inserted. Internal connecting pins of the connector strip 26 run to both circuit boards 14 and rest with their end areas sprung against assigned conductor track sections in each case. Identified in FIG. 1 are a connecting pin 28-1 running to the lower circuit board 14-1 and a connecting pin at 28-2 running to the upper circuit board 14-2.

The spacer arrangement 18 is formed here from three parts which are separate and which thus support the circuit board arrangement in different areas, of which a cross sectional view can be seen in FIG. 1.

To assemble the electronic unit 10 the lower circuit board 14-1, already equipped with electronic components 12, is placed on the inside of the lower housing section. Then the parts of the spacer are placed on the upper side of this circuit board 14-1. Finally the upper circuit board 14-2 and on top of this an upper housing section are installed, and the upper section is connected to the lower section of the housing. The assembly of a housing from a number of housing sections is well known in technology and does not need to be explained in any greater detail here. There is provision for the function of the spacer arrangement 18 to hold the circuit boards 14 and for electrical connection of these circuit boards for the housing arrangement in the connected state to exert a greater or lesser force directed downwards onto the circuit boards 14 so that the electrical connection between the circuit boards by means of spacer arrangement 18 is securely guaranteed.

In the following description of further exemplary embodiments the same reference numbers are used for similar components but the numbers are supplemented by a lowercase letter to identify the embodiment. In these cases essentially only the differences from the embodiment or embodiments already described are discussed and otherwise explicit reference is made to the description of previous exemplary embodiments.

FIGS. 2-4 illustrate examples of different designs of a spacer arrangement that could be used for the invention which are overlaid by a circuit board in each case and that can actually support the circuit board on the one hand and on the other hand connect it electrically with a further circuit board located under the spacer arrangement.

To occupy as little space as possible while still providing good support, the one-piece plastic spacers 18a, 18b and 18c are each formed from straight sections running lengthwise.

Spacer 18a shown in FIG. 2 has four long sections, each running along one edge of circuit board 14a-2, which each extend out over the edge of this circuit board and together form an enclosed frame running around the circumference of this circuit board. In practice this spacer frame provides especially good support for the circuit boards which lie against it.

Spacer 18b shown in FIG. 3 is approximately U-shaped when seen from above and is formed from three sections running lengthwise.

Spacer 18C shown in FIG. 4 again features sections running along the edge of the circuit board. However an additional section running across under circuit board 14c-2 from one edge of this circuit board to the opposite edge of this circuit board is provided.

With the spacers shown in FIGS. 2-4 one or more cutouts can again be provided to accept a connector strip (cf. 26 in FIG. 1). In addition electronic components can be mounted on the inside of the spacer sections running around the edge and/or on a section crossing the adjacent circuit board, for which electrical contact is only established when the electronic unit is assembled.

Each of the spacer arrangements 18a, 18b and 18c provides an electrical connection of the two adjacent circuit boards at the desired point. This is not shown in FIGS. 2-4. Various options for this are described with reference to FIGS. 5-9

With reference to FIGS. 5-9, a number of typical examples of spacers are given below with regard to their function for electrical connection of a pair of circuit boards. In each example a section through a spacer equipped with electrically-conducting connection elements is shown.

FIG. 5 illustrates a spacer 18d with connection elements 20d which extend vertically over the external surface of the spacer 18d and are connected by their center section to this surface. Connection elements 20d are embodied as metal spring tongues, the ends of which make spring contact with one of the two adjacent circuit boards and for this purpose each slightly protrude beyond the upper and lower edge of spacer 18d when not under tension, so that secure electrical contact is guaranteed in the assembled state.

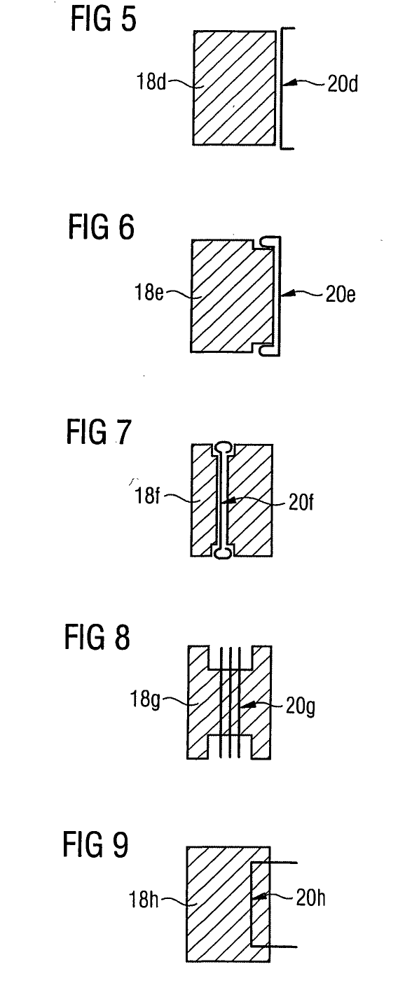

FIG. 6 illustrates an embodiment in which spring tongues 20e penetrate with their upper and lower ends into suitably formed steps in the upper and lower edges of a spacer 18e and are held on the spacer in this way.

FIG. 7 illustrates an arrangement of spring tongues 20f running through the inside of a spacer 18f.

In the embodiment in accordance with FIG. 8 connection elements 20g have been directly molded into the spacer material (plastic) during manufacturing of a spacer 18g. FIG. 9 shows a similar embodiment in which however connection elements 20h form spring tongues running transversely, which are intended to establish a spring connection with contact elements already located on the circuit boards (e.g. pins).

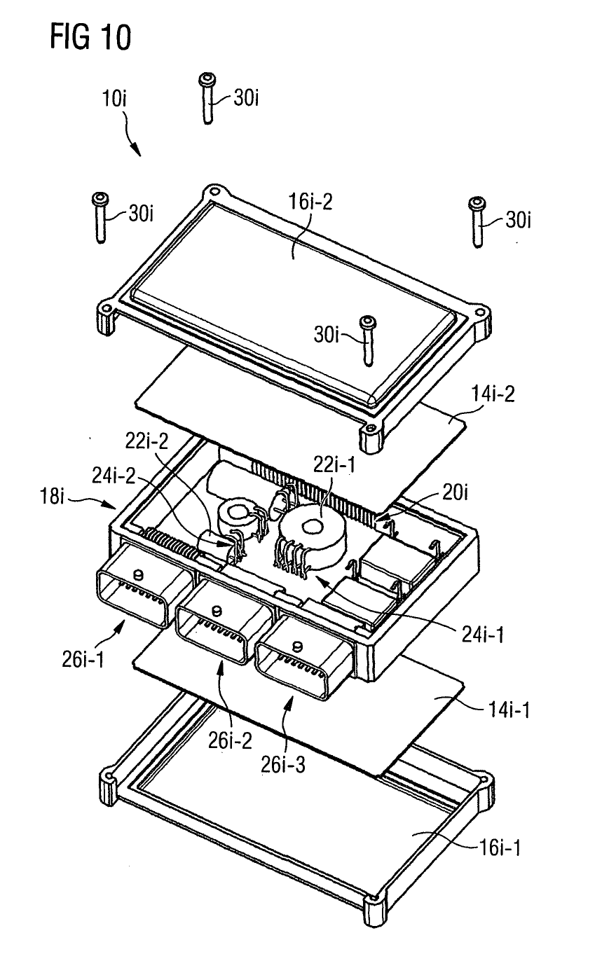

FIGS. 10-14 shows a further exemplary embodiment of an electronic unit 10i in the form of a control unit for a motor vehicle with which motor control functions in particular are to be implemented.

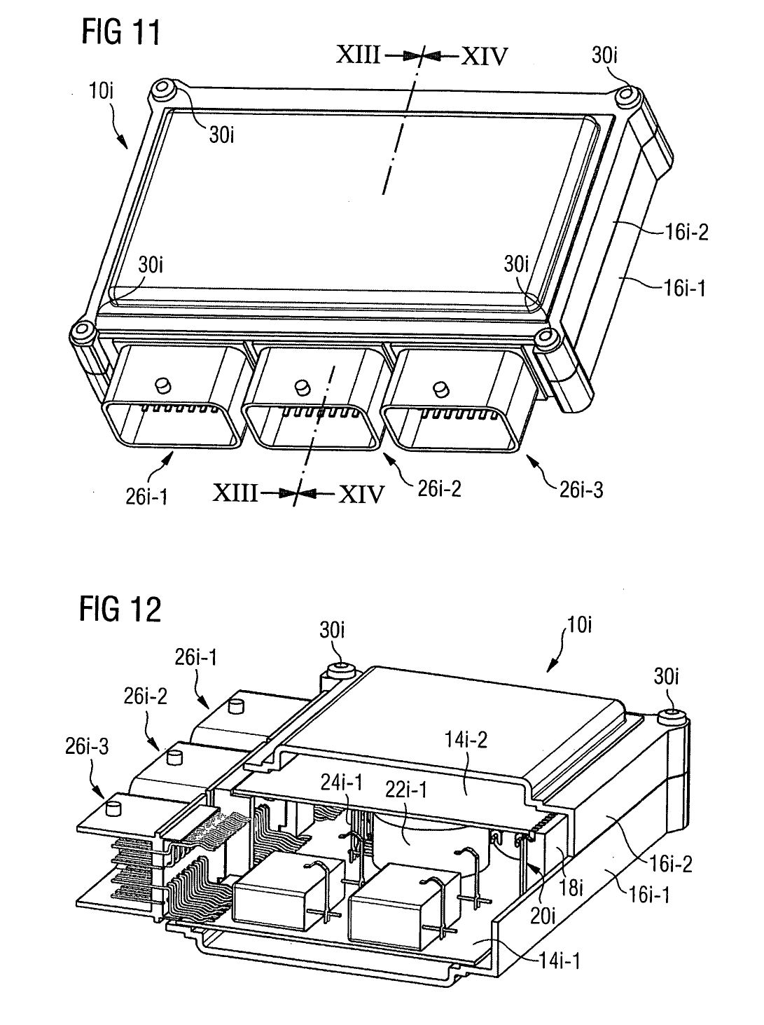

The housing which overall is rectangular in shape is formed in this embodiment by a lower housing cover 16i-1 and an upper housing cover 16i-2 attached to it by means of screws 30i, which in the closed state of the housing (FIGS. 11-14) are against each other on three edges. Along the fourth edge the housing 16 there is a cutout to accommodate three connector strips 26i arranged next to one another which serve to connect the control unit 10i to the wring harness of a motor vehicle.

These connector strips 26i are each provided in a cutout on the edge of a one-piece plastic molded spacer 18i.

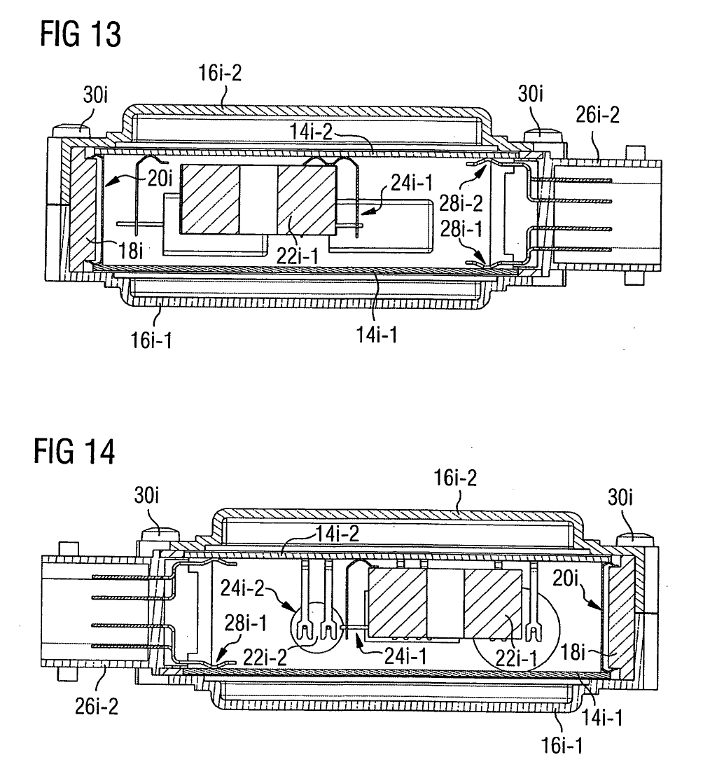

Spacer 18i holds two adjacent circuit boards 14i-1 and 14i-2 in the closed state of the housing 16 at a desired distance apart which is determined by the vertical extent of spacer 18i. The flat sides of circuit boards 14i facing away from spacer 18i are, in the closed state of housing 16i in the exemplary embodiment shown, subject to a direct load on their edges from the relevant housing cover, as is easy to see from FIGS. 13 and 14. Housing 16i thus exerts a clamping force on spacer 18i.

At the same time spacer 18i provides an electrical connection between the two circuit boards 16i on the opposite side from the connector strips 26i. This electrical connection is realized in this case by a plurality of connection elements 20i running vertically and arranged next to each other in a form of individual metal spring strips of which the ends in the close state of housing 16i are in direct contact with the assigned conductor tracks of the circuit boards 14i.

Internal connection pins 28i of the connector strips 26i come into immediate contact with their ends with the assigned conductor tracks of circuit boards 14i.

The electronic circuit arrangement of control unit 10i also comprises, in addition to the electronic components (not shown) which are soldered onto the flat sides of circuit boards 14i, a plurality of further electronic components which during the manufacturing of the control unit 10i are only connected electrically to one or other of the two circuit boards 14i when the housing 16i is closed. In the Figures two of these further electronic components are identified as 22i-1 and 22i-2. Connection pins of these further electronic components 22i are electrically connected to the upper circuit board 14i-2 via connection pin arrangements 24i-1 and 24i-2. When the control unit 10i is manufactured these further electronic components 22i are initially attached in a suitable way inside the spacer 18i. To make the diagram clearer the means used to attach the components are not shown in the Figure. The components can for example be inserted by means of snap-in connections to sections of spacer 18i designed to accept them.

In the exemplary embodiment shown the connection in arrangement 24i consists in each case of the connection pins belonging to the relevant components which are continued by a metal strip running through to the relevant circuit board 14i. For this purpose the component-side end of this metal strip is embodied as a forked insulation displacement contact which thus encloses the relevant connection pin of the component and can provide a reliable electrical transfer contact. The ends of this metal strip away from the components form spring contacts which, when housing 16i is closed, make sprung contact with the corresponding conductor tracks. These further electrical components are thus “automatically” contacted during assembly of control unit 10i.

What we claim is:

1. An electronic unit for a motor vehicle, comprising:
a plurality of circuit boards arranged one above the other and equipped with at least a first electronic component,
a spacer between adjacent boards to form an electrical interconnection between adjacent boards,
a housing to accept the circuit boards, said housing pressing the circuit boards together to hold the spacer between the boards, and
at least one second electronic component attached to the spacer having at least one connection pin in electrical contact with one of the circuit boards.

2. An electronic unit in accordance with claim 1, wherein the circuit boards are rigid.

3. An electronic unit in accordance with claim 1, wherein the adjacent circuit boards have essentially the same format and are essentially arranged above one another so that they cover the same area.

4. An electronic unit in accordance with claim 1, wherein the spacer comprises at least one section running essentially lengthwise in a straight-line.

5. An electronic unit in accordance with claim 1, wherein the spacer comprises at least one section extending from one edge to the opposite edge of one of the adjacent circuit boards.

6. An electronic unit in accordance with claim 1, wherein the spacer comprises at least one section running lengthwise along one edge of the adjacent circuit boards.

7. An electronic unit in accordance with claim 1, wherein the spacer comprises at least one section extending beyond the edge of one of the adjacent circuit boards.

8. An electronic unit in accordance with claim 1, wherein the spacer comprises at least one section extending as a frame around the circumference of one of the adjacent circuit boards (14).

9. An electronic unit in accordance with claim 1, wherein the spacer further comprises a plurality of electrically conducting connection elements arranged next to each other, said elements having electrical contact ends to make contact with a circuit board.

10. An electronic unit in accordance with claim 1, wherein the at least one second electronic component is attached to the spacer such that a connection pin of the second component is in spring contact with a conductor track of one of the adjacent circuit boards to establish an electrical connection.

11. An electronic unit in accordance with claim 1, wherein the at least one second electronic component is attached to the spacer such that a connection pin of the second component is gripped by a fork-shaped insulation displacement contact of one of the adjacent circuit boards to establish an electrical connection.

12. An electronic unit in accordance with claim 1, wherein the second electronic component is attached to the spacer via a snap-in connection to a section of the spacer designed to accept it.

13. An electronic unit in accordance with claim 1, wherein the spacer comprises at least one cut out section for accommodating a connector strip for connecting the electronic unit to an external cable arrangement such that at least one part of an internal connection pin of the connector strip makes electrical contact with one or the other of the adjacent circuit boards.

14. An electronic unit in accordance with claim 1, wherein the housing comprises a lower housing cover as well as an upper housing cover connected to it.

15. A method for manufacturing an electronic unit for a motor vehicle, said method comprising:
arranging a plurality of circuit boards equipped with at least one electronic component above one another in a housing, and
electrically connecting the circuit boards to each other by arranging a spacer between adjacent circuit boards to provide an electrical connection between adjacent circuit boards,
pressing the adjacent boards together via a force provided by the housing, and
attaching at least one second electronic component to the spacer via at least one connection pin of said second component to make electrical contact with one of the adjacent boards.
